(19) United States
(12) Patent Application Publication
(10) Pub. No.: US 2018/0054871 A1
(43) Pub. Date: Feb. 22, 2018

(54) OPTOELECTRONIC COMPONENT AND METHOD FOR EXCHANGING AN OPTOELECTRONIC COMPONENT

(71) Applicant: OSRAM OLED GmbH, Regensburg (DE)

(72) Inventors: Michael Popp, Freising (DE); Kilian Regau, Regensburg (DE); Thorsten Vehoff, Regensburg (DE)

(21) Appl. No.: 15/556,636

(22) PCT Filed: Mar. 9, 2016
(86) PCT No.: PCT/EP2016/054960

§ 371 Date: Sep. 8, 2017

(30) Foreign Application Priority Data
Mar. 11, 2015 (DE) 10 2015 204 360.6

(51) Int. Cl. H05B 33/08; H05B 37/04; B41J 3/01; B41J 3/28; B41J 3/407; H01L 27/32; H01L 27/28; H01L 51/52

(52) U.S. Cl. CPC H05B 33/0896; H05B 37/04; B41J 3/01; B41J 3/28; H01L 51/5271; H01L 27/3269; H01L 27/322; H01L 27/288; H01L 51/5262; B41J 3/407

(57) ABSTRACT

According to the present disclosure, an optoelectronic component is provided with an organic layer stack, in which light is generated in operation of the optoelectronic component, at least one marking element, by means of which the optoelectronic component is identifiable, wherein the at least one marking element can be read out under irradiation using electromagnetic radiation from the nonvisible spectral range, the at least one marking element can be read out at a main surface of the optoelectronic component, and wherein the at least one marking element is arranged at or under the main surface in the region of the illuminated area.

Document US 2007/0194719 A1 describes an optoelectronic component.

One object to be achieved is to specify an optoelectronic component which is particularly easily identifiable.

An optoelectronic component is specified. The optoelectronic component can be, for example, an organic optoelectronic component. It is possible in this case that it is a radiation-emitting organic optoelectronic component, in particular an organic light-emitting diode (OLED).

According to at least one embodiment of the optoelectronic component, the optoelectronic component includes an organic layer stack, in which light is generated in operation of the optoelectronic component. Colored or white light can be generated in the organic layer stack of the optoelectronic component, so that the optoelectronic component emits colored or white light in operation. The optoelectronic component can emit the light from one side or from two opposite sides of the component. In the latter case, the optoelectronic component can be a component which is radiation-transmissive in places, for example, a so-called “transparent OLED”.

According to at least one embodiment of the optoelectronic component, the optoelectronic component includes a main surface, in particular two main surfaces, which are arranged opposite to one another. Each main surface of the optoelectronic component represents a part of the outer surface of the optoelectronic component. For example, one main surface is arranged on the side of the optoelectronic component facing away from a carrier of the optoelectronic component. The opposing main surface is then formed by a part of the outer surface of the carrier.

At least one of the main surfaces of the optoelectronic component includes an illuminated area which occupies a majority of the area of the main surface. For example, the proportion of the illuminated area on the main surface is at least 50%, in particular at least 75%. The illuminated area of the optoelectronic component is the area through which at least a part of the light generated in operation of the optoelectronic component leaves this component. The optoelectronic component may include multiple illuminated areas in this case, which are arranged adjacent to one another in a lateral direction, which extends in parallel to the main surface, for example. Furthermore, it is possible that the optoelectronic component has one illuminated area on the one main surface and a further illuminated area on the opposing side of the optoelectronic component within the main surface provided there. The optoelectronic component is in this case a two-sided optoelectronic component, which can be embodied in part as a “transparent OLED”, for example.

At least a part of the light generated in operation leaves the optoelectronic component through the illuminated area, so that the optoelectronic component emits the light from its illuminated area.

According to at least one embodiment of the optoelectronic component, the optoelectronic component includes at least one marking element, by means of which the optoelectronic component is identifiable. The marking element can be, for example, a symbol, an inscription, a graphic representation, in particular a pictogram, and/or a coded representation, for example, a barcode or a dot matrix code.

The optoelectronic component is at least indirectly identifiable on the basis of the at least one marking element. “Identifiable” is understood here and hereafter to mean that the optoelectronic component can be assigned, at least with respect to a partial aspect of the optoelectronic component, to a group or a class of optoelectronic components and/or the optoelectronic component can be uniquely differentiated from all other optoelectronic components of identical construction.

For example, the producer of the optoelectronic component can be identifiable on the basis of the at least one marking element, so that the optoelectronic component is assignable to a group of components of the producer. Furthermore, it is possible that the construction or the product class of the optoelectronic component is recognizable on the basis of the at least one marking element. Finally, it is also possible that a production number, in which items of information such as the producer, the production location, and the production time period can be coded, of the optoelectronic component is recognizable on the basis of the at least one marking element. In the extreme case, it is possible to uniquely identify the optoelectronic component on the basis of the at least one marking element, such that it is differentiable from all other optoelectronic components of identical construction. It is possible in this case that the optoelectronic component includes two or more different marking elements, on the basis of which different items of information about the optoelectronic component can be coded.

According to at least one embodiment of the optoelectronic component, the at least one marking element can be read out under irradiation using electromagnetic radiation from the spectral range which is nonvisible to the human observer. This means that the marking element may include a material, for example, which after excitation using electromagnetic radiation from the nonvisible spectral range, for example, using UV radiation, has a characteristic emission in the visible or infrared spectral range, which can be read out and therefore acquired by the human observer or a detection device, which includes at least one photodiode or one CCD sensor, for example. The information read out in this manner can be further processed automatically, for example, to identify the optoelectronic component.

According to at least one embodiment of the optoelectronic component, the at least one marking element can be read out at a main surface of the optoelectronic component. This means that the marking element can be read out under irradiation of the main surface using the electromagnetic radiation from the nonvisible spectral range. The marking element is therefore not arranged at an area which is difficult to access, for example, such as a lateral surface of the optoelectronic component, but rather the marking element is located directly at a main surface of the optoelectronic component, which may also include the illuminated area. The at least one marking element does not have to be arranged on the outer surface of the main surface in this case, but rather the at least one marking element can be arranged at any arbitrary point within the optoelectronic component below the main surface.

According to at least one embodiment of the optoelectronic component, the optoelectronic component includes an organic layer stack, in which light is generated in operation of the optoelectronic component, and at least one marking element, by means of which the optoelectronic component is identifiable, wherein the at least one marking element can be read out under irradiation using electromagnetic radiation from the nonvisible spectral range, and the at least one marking element can be read out at a main surface of the optoelectronic component.

The optoelectronic component described here is based, inter alia, on the finding that easy recognizability and/or tracking capability of the optoelectronic component is particularly easily possible in the case where at least one marking element, which can be read out under irradiation using electromagnetic radiation from the nonvisible spectral range, can be read out via a main surface of the optoelectronic component. In this case, it is often possible to identify the optoelectronic component without prior removal of the optoelectronic component from its intended location. The marking element can be read out in this case, for example, by irradiation using infrared radiation or UV radiation.

According to at least one embodiment of the optoelectronic component, the main surface includes an illuminated area, through which at least a part of the light generated in operation leaves the optoelectronic component. It is possible in this case that each of the two main surfaces of the component includes an illuminated area. Furthermore, it is possible that the optoelectronic component only emits light from its base surface or from its cover surface in operation and only this main surface then includes the illuminated area.

An optoelectronic component having a marking element which can be read out on the main surface of the optoelectronic component, which also includes the illuminated area, can also be identifiable in the installed state. This enables, for example, the provision of a structurally-equivalent optoelectronic component, without the identified optoelectronic component having to be removed from its intended location beforehand.

Furthermore, it is possible that the optoelectronic component can also be identified on the basis of the at least one marking element if only fractions of the optoelectronic component are present, so that, for example, destroyed optoelectronic components are also identifiable on the basis of the at least one marking element.

According to at least one embodiment of the optoelectronic component, the at least one marking element is not visible to the human observer and can exclusively be read out under irradiation using the electromagnetic radiation from the nonvisible spectral range. This means that although the marking element can be read out at a main surface of the optoelectronic component and therefore at a point of the optoelectronic component which is often also visible to the human observer without removal or exposure of the optoelectronic component, the at least one marking element is designed such that under normal light conditions, for example, under visible artificial light or daylight, it is not recognizable to the human observer. The marking element first becomes visible upon irradiation of the at least one marking element using the electromagnetic radiation from the nonvisible spectral range. It is possible in this case that the marking element emits light in the visible spectral range under this irradiation, so that the human observer directly receives items of information about the optoelectronic component on the basis of the marking element.

According to at least one embodiment of the optoelectronic component, the at least one marking element, upon the irradiation using the electromagnetic radiation from the nonvisible spectral range, emits further electromagnetic radiation from the nonvisible spectral range, which is different from the electromagnetic radiation from the nonvisible spectral range. For example, it is possible that the marking element is irradiated using UV radiation and emits radiation in the infrared range as the further nonvisible electromagnetic radiation. In such a case, the irradiated marking element is also not recognizable by the human observer and has to be read out using electronic aids, for example, a detection element. In this case, the optoelectronic component is based on the finding, inter alia, that in this manner an unintentional excitation of the at least one marking element, for example, by intensive sunlight and its UV component can be prevented. Furthermore, the optoelectronic component is based, inter alia, on the finding that markings which are not directly visible to the human eye do not have to be concealed at the intended location of the optoelectronic component.

According to at least one embodiment of the optoelectronic component, the at least one marking element is arranged in a lateral direction at or below the main surface laterally to the illuminated area. For example, the illuminated area at the main surface is enclosed by a region in which contact points for contacting the optoelectronic component are located. No light exits from these points of the optoelectronic component in operation, so that the marking element, even in the event of unintentional irradiation using the nonvisible electromagnetic radiation, cannot interfere with the illumination image of the light emitted from the optoelectronic component.

According to at least one embodiment of the optoelectronic component, the at least one marking element is arranged at or below the main surface in the region of the illuminated area. In this case, the marking element is particularly clearly recognizable. It has proven to be advantageous in this case if the marking element, upon excitation by the non-visible electromagnetic radiation, also emits electromagnetic radiation in the further nonvisible spectral range, so that even in the event of unintentional illumination using the nonvisible electromagnetic radiation, no interference with the illumination image of the light emitted by the optoelectronic component in operation occurs.

For the case in which the optoelectronic component includes two or more marking elements, at least one of the marking elements can be arranged laterally to the illuminated area and at least one of the marking elements can be arranged in the region of the illuminated area. In this case, it is also possible upon the use of multiple marking elements that the marking elements are embodied differently and bear different items of information. This means it is also possible that at least one of the marking elements emits light in the visible spectral range upon excitation and is therefore visible to the human observer and at least one of the marking elements emits light in the further nonvisible spectral range and can therefore be read out using an electronic aid. Furthermore, it is possible that different marking elements are excited using electromagnetic radiation from different spectral ranges and/or emit electromagnetic radiation from different spectral ranges, for example, having different colors.

According to at least one embodiment of the optoelectronic component, the at least one marking element is arranged between two parts of the optoelectronic component. This means the marking element is integrated at a certain point in the optoelectronic component, wherein it is not also incorporated into a part of the optoelectronic component, but rather is arranged between two parts of the optoelectronic component. Such a marking element is particularly simple to also introduce into the optoelectronic component. The parts of the optoelectronic component can be in this case, for example, the main surface, a carrier, the organic layer stack, an insulation which is formed using an electrically nonconductive material, a first electrode, a second electrode, an encapsulation, in particular an encapsulation layer or an encapsulation layer sequence, a bonding means, for example, an adhesive, or a cover.

According to at least one embodiment of the optoelectronic component, the at least one marking element is arranged inside a part of the optoelectronic component. In this case, the marking element is thus incorporated into a part of the optoelectronic component which is provided in any case, for example, one of the listed parts. The optoelectronic component can be embodied as particularly thin in this case, for example, because its presence does not increase the thickness of the optoelectronic component measured in a vertical direction, which extends perpendicularly in relation to the lateral direction.

According to at least one embodiment of the optoelectronic component, the optoelectronic component includes at least two marking elements, wherein the marking elements are arranged offset and/or spaced apart in relation to one another in a lateral direction and/or a vertical direction. The lateral direction is in this case a direction which extends, for example, in parallel to the main surface of the optoelectronic component in the scope of the production tolerance. The vertical direction is a direction which can extend transversely or perpendicularly in relation to the lateral direction and, for example, extends in parallel to the stack direction of the organic layer stack in the scope of the production tolerance. The marking elements of the optoelectronic component can be arranged spaced apart in relation to one another in the vertical direction and offset in relation to one another in the lateral direction, for example. The marking elements can each be read out at the main surface in this case, wherein they can be read out at different points of the main surface.

According to at least one embodiment of the optoelectronic component, the at least one marking element is formed using a sensitive phosphor and the at least one marking element is arranged inside an encapsulation of the optoelectronic component. A sensitive phosphor is, here and hereafter, a phosphor which can be excited using electromagnetic radiation from the nonvisible spectral range and which emits electromagnetic radiation from another spectral range, for example, in the visible spectral range, or in the further nonvisible spectral range. The phosphor is sensitive in this case with respect to corrosion under damp conditions, atmospheric gases, or elevated temperature. In particular, the sensitive phosphor can be an organic phosphor and/or a so-called quantum dot converter. Such phosphors can be distinguished, inter alia, in that they emit electromagnetic radiation at particularly high intensity and/or in a particularly narrow wavelength range under excitation. They are therefore particularly well suited for forming the marking elements described here. The introduction of marking elements, which are formed using such a sensitive phosphor, within the encapsulation of the optoelectronic component, such that the marking element is also protected in the same manner as the organic layer stack by the encapsulation, has proven to be particularly advantageous, because in this manner the marking element also profits from the good encapsulation of the organic layer stack of the optoelectronic component.

According to at least one embodiment of the optoelectronic component, the at least one marking element includes at least one of the following materials:
fluorescent materials, the emission of which decays rapidly after excitation using, for example, UV radiation, in particular excitable using blacklight UV-A radiation;
fluorophores, also having an emission in different colors, for example for coding different production time periods, producers, and the like;
quinine, rhodamine B, diphenyl anthracene, rubrene, berberine, coumarin, aesculin, zinc sulfide, for example, doped with copper and/or aluminum, for the emission of green light;
oxides of the rare earth elements such as scandium, lanthanum, cerium, praseodymium, neodymium, promethium, samarium, europium, in which the emission color is settable by the selection of activators;
fluorescent colorants such as fluorescein, xanthine colorants;
direct semiconductors, for example, as a quantum dot phosphor: the excitation is performed using high-energy light here, wherein ideally the band edge of the semiconductor is below the wavelength of blue light, whereby the marking element is transparent in the visible range, and opaque to UV radiation, for example, GaN/AlN, ZnOx, SiC, ZnS;
semiconductors which emit in the visible range, such as InAlGaAs, InGaAlP;
converter materials as described in another context in document DE 102012021570, which is hereby expressly incorporated by reference with respect to the disclosure of converter materials;
orthosilicates, thiogallates;
infrared-excitable phosphors such as barium chloride, strontium chloride, YOCI, LaBr, barium halogenide with or without erbium;
Bragg mirrors for IR radiation, in which a reflection of IR radiation occurs, which can be detected using a photodiode, for example.

Furthermore, a method for exchanging an optoelectronic component is specified. Using the method it is possible, for example, to exchange an optoelectronic component described here, i.e., to remove it from its intended location and replace it with another, in particular identical, optoelectronic component. All features described here for the optoelectronic component are therefore also disclosed for the method and vice versa.

According to at least one embodiment of the method, the method includes the following steps:

Firstly, the main surface of an optoelectronic component is irradiated using electromagnetic radiation from the nonvisible spectral range. At least one marking element can be read out at the main surface of the optoelectronic component, which can be read out under the irradiation using the electromagnetic radiation from the nonvisible spectral range and which is arranged at or under the main surface. This marking element is read out.

In a subsequent method step, the optoelectronic component is identified on the basis of the marking element and an exchange of the optoelectronic component with a structurally-equivalent optoelectronic component is performed. This means, via the identification of the optoelectronic component by means of the at least one marking element, it is possible to ascertain a structurally-equivalent optoelectronic component and to exchange the optoelectronic component accordingly. The method described here is preferably carried out in the specified sequence in this case.

The optoelectronic components described here and the method described here are explained in greater detail hereafter on the basis of embodiments and the associated figures.

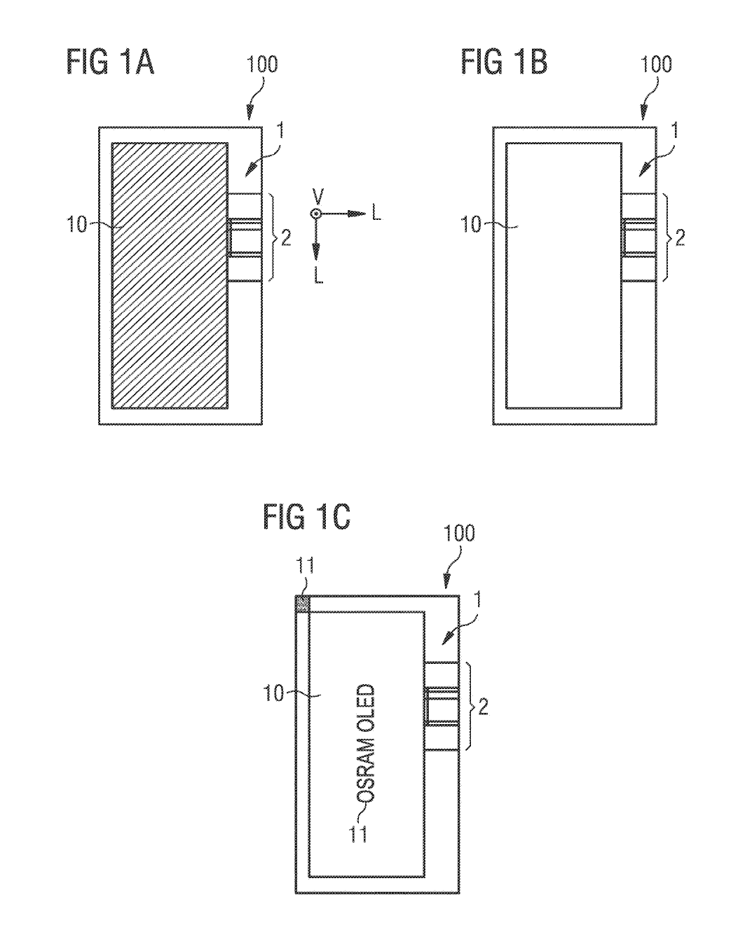

Embodiments of components described here are explained in greater detail on the basis of the schematic illustrations of FIGS. 1A, 1B, 1C, 2A, 2B, 3A, 3B, 4A, 4B, 5A, 5B, 6A, 6B, 6C, 6D, 7A, 7B.

Identical, equivalent, or identically-acting elements are provided with identical reference signs in the figures. The figures and the size relationships of the elements shown in the figures in relation to one another are not to scale. Rather, individual elements can be shown exaggeratedly large for better illustration and/or for better comprehension.

FIGS. 1A to 1C show a first embodiment of an optoelectronic component described here on the basis of schematic top views of the main surface 1. The optoelectronic component is, for example, an organic light-emitting diode (OLED). The illuminated area 10 is arranged on the main surface 1 of the optoelectronic component 100.

The optoelectronic component 100 emits the generated light in operation from the illuminated area 10. The illuminated area 10 only occupies a part of the main surface 1 in this case and is enclosed in a frame-like manner by a region which encloses the illuminated area 10 in the lateral directions L, which extend in parallel to the main surface 1, for example. Outside the illuminated area 10, the contact points 2, using which the optoelectronic component 100 can be electrically contacted from the outside, are arranged on the main surface 1. FIG. 1A shows the optoelectronic component schematically in the turned-on state, in which the illuminated area 10 emits light, represented by the shading of the area 10.

FIG. 1B schematically shows the same optoelectronic component in the turned-off state, in which no light is emitted from the illuminated area 10.

FIGS. 1A and 1B each show the optoelectronic component 100 in a state in which the optoelectronic component is not irradiated using electromagnetic radiation from the nonvisible spectral range.

In contrast thereto, FIG. 1C shows the state of the optoelectronic component when it is irradiated using electromagnetic radiation from the nonvisible spectral range, under which the marking elements 11 can be read out. Under irradiation using this electromagnetic radiation, which can be, for example, UV radiation or infrared radiation, depending on the material which is used to form the marking elements, the marking elements 11 can be read out. For example, the optoelectronic component includes two marking elements 11 in the present case. A first marking element 11 is formed as a dot matrix code and can be read out at the main surface 1, wherein the marking element can be read out outside the illuminated area 10. The second marking element is formed as a symbol or inscription, which can be read out at the illuminated area 10. Both marking elements can bear different items of information. Thus, the marking element which is formed as a dot matrix code can bear, for example, items of information such as a component number, a manufacturing date, a manufacturing location, and the like. The marking element which can be read out at the illuminated area 10 can be, for example, a producer logo or a tradename. The marking elements 11 can, upon the irradiation by the nonvisible electromagnetic radiation, emit further nonvisible electromagnetic radiation, for example, which is read out with an aid, or they can emit in the range of visible light. In this case, the different marking elements can differ with respect to the type of emission as visible or nonvisible, respectively.

In this case, it is shown in FIG. 1C that two marking elements 11 are arranged offset in relation to one another in the lateral direction L. However, it would also be possible that two or more marking elements are arranged not offset in the lateral direction and one above another in the vertical direction V. In this case, in particular marking elements can be used which emit electromagnetic radiation from different spectral ranges under excitation, so that accordingly different items of information can be read out in the different spectral ranges. For example, an emission in the infrared range, which can be read out using an aid, can be overlaid by an emission in the visible range, which can be recognized with the naked eye, so that the user who reads out the information obtains items of information about where he can read out the nonvisible information and can place the detection or readout device accordingly.

Further embodiments of optoelectronic components described here are explained in greater detail on the basis of the schematic sectional illustration of the following figures.

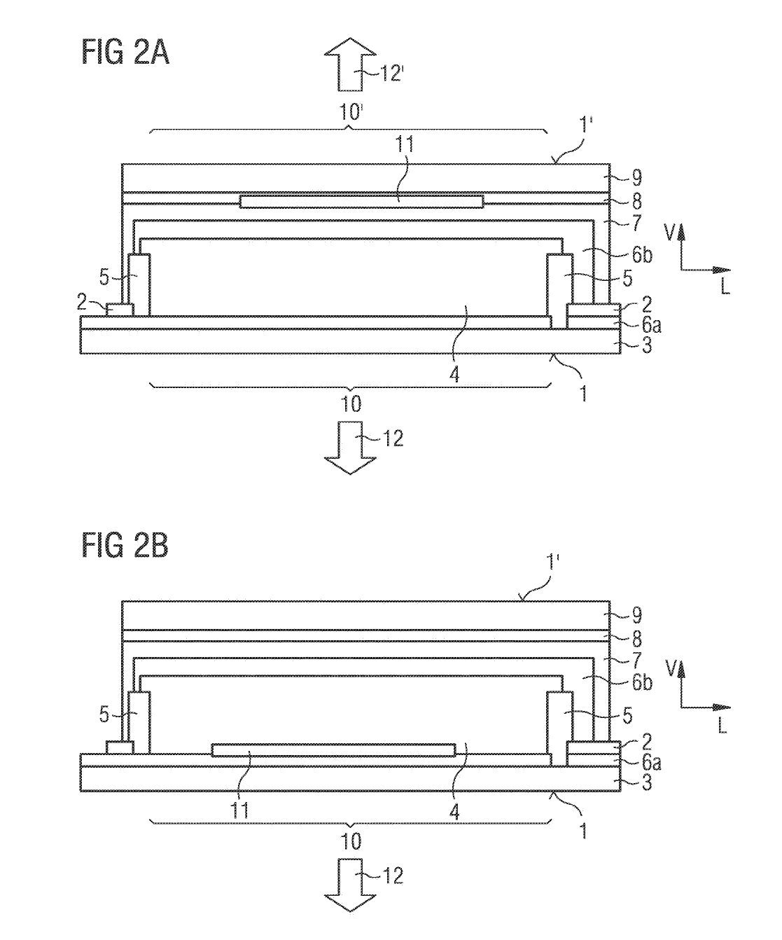

An optoelectronic component is shown in conjunction with FIG. 2A which has a carrier 3, which is formed using a radiation-transmissive material, for example. The carrier 3 can be formed using glass or a film, for example. The first electrode 6a, which is embodied as radiation-transmissive at least in part and is formed for this purpose, for example, using a material such as a transparent conductive oxide (TCO) and/or a thin metal film, is arranged on the upper side of the carrier 3.

The organic layer stack 4, in which the light 12 emitted by the optoelectronic component 100 is generated in operation, adjoins on the side of the first electrode 6a facing away from the carrier 3.

The second electrode 6b, which is electrically insulated by an insulation 5 from the first electrode 6, adjoins on the upper side of the organic layer stack 4 facing away from the carrier 3. The first electrode 6a and the second electrode 6b are electrically conductively connected to different contact points 2, which can be contacted from outside the optoelectronic component 100.

The first and/or the second electrode can, for example, contain at least one of the following materials or can consist of one of these materials: ITO, graphene, Mo, Al, Cr, Ag, Mg.

The second electrode 6b can be designed as radiation-transmissive or radiation-reflective. The optoelectronic component 100 which is described in conjunction with FIG. 2B or in conjunction with one of the other figures can be a component which emits on one side, for example, a top emitter or a bottom emitter, or a component which emits on two sides, for example a transparent OLED. If it is a component which emits on two sides, light 12 is thus emitted from the illuminated area 10 at the main surface 1 and further light 12′ is emitted from the further illuminated area 10′ at the further main surface 1′.

At least the organic layer stack 4 is enclosed by the encapsulation layer 7, which can be, for example, a thin-film encapsulation, a cavity encapsulation, or the like. The encapsulation 7 can also contain, for example, at least one ALD layer, which is produced by means of an ALD method (ALD—atomic layer deposition).

On the side of the encapsulation 7 facing away from the carrier 3, in the embodiment of FIG. 2B, a bonding agent 8 follows, for example an adhesive, via which a cover 9 is bonded to the encapsulation 7. The cover 9 can be, for example, a plastic film, a metal film, and/or a thin glass. The cover 9 is used, for example, for the mechanical protection of the optoelectronic component 100, in particular as scratch protection for the encapsulation 7.

Furthermore, it is possible that in the embodiment of FIG. 2A, the second electrode 6b is formed as reflective. In this case, the marking element 11 can be read out from the main surface 1′ facing away from the illuminated area 10. This main surface 1′ then does not include a further illuminated area 10′.

The embodiment of the second electrode 6b as a reflective or as a transparent electrode is possible in all embodiments described here.

In the embodiment of FIG. 2B, a marking element 11 is arranged in the region of the illuminated area 10 between the encapsulation 7 and the adhesive 8, wherein the marking element 11 can be covered by the adhesive 8, which also functions in this manner as a planarization layer. The marking element 11 can be formed as intransparent, for example. In this case, the cover 9 is formed as reflective at least in part. The marking element 11 can be read out at the main surface 1 in the region of the illuminated area 10.

In contrast thereto, the embodiment of FIG. 2B shows a marking element 11 which is designed as transmissive to visible light and which is arranged in the region between the first electrode 6a and the organic layer stack 4. This marking element 11 can also be read out at the main surface 1 in the region of the illuminated area 10. It is also possible in this case that the two marking elements shown in FIGS. 2A and 2B are provided jointly in a single optoelectronic component 100 and upon illumination using the electromagnetic radiation in the nonvisible spectral range, emit electromagnetic radiation from spectral ranges which differ from one another.

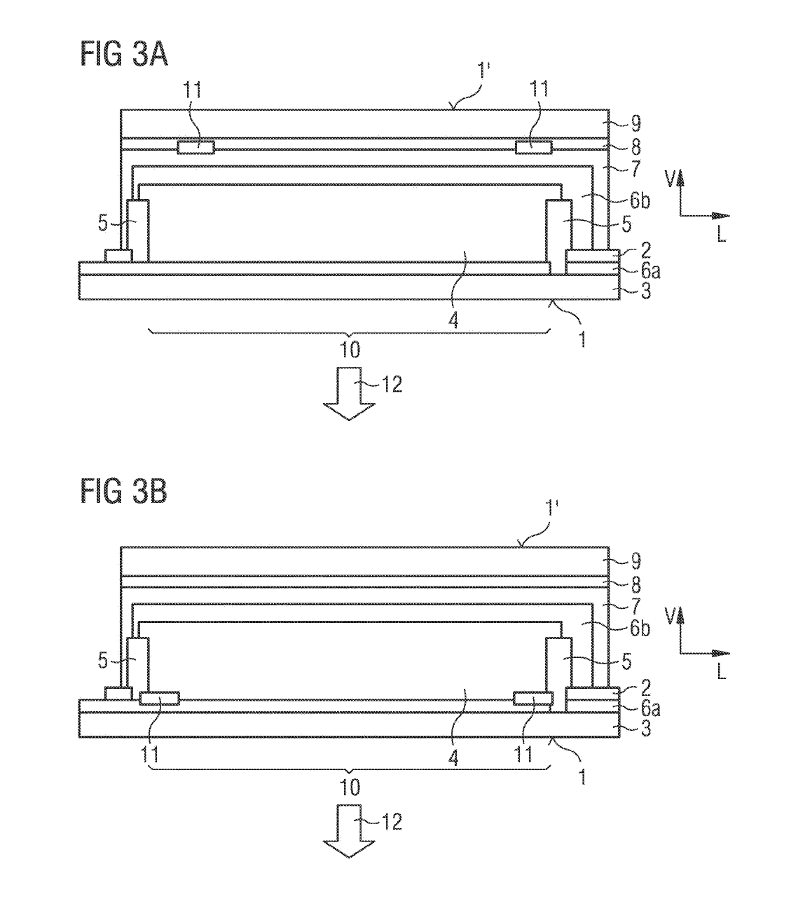

The embodiments illustrated in conjunction with FIGS. 3A and 3B correspond to the embodiments shown in conjunction with FIGS. 2A and 2B, wherein two or more marking elements 11 are arranged laterally spaced apart, but vertically at the same height in relation to one another in these embodiments. This means the marking elements 11 have no distance from one another in the vertical direction V. In this case, different items of information can be coded via different marking elements, wherein the marking elements can be embodied differently.

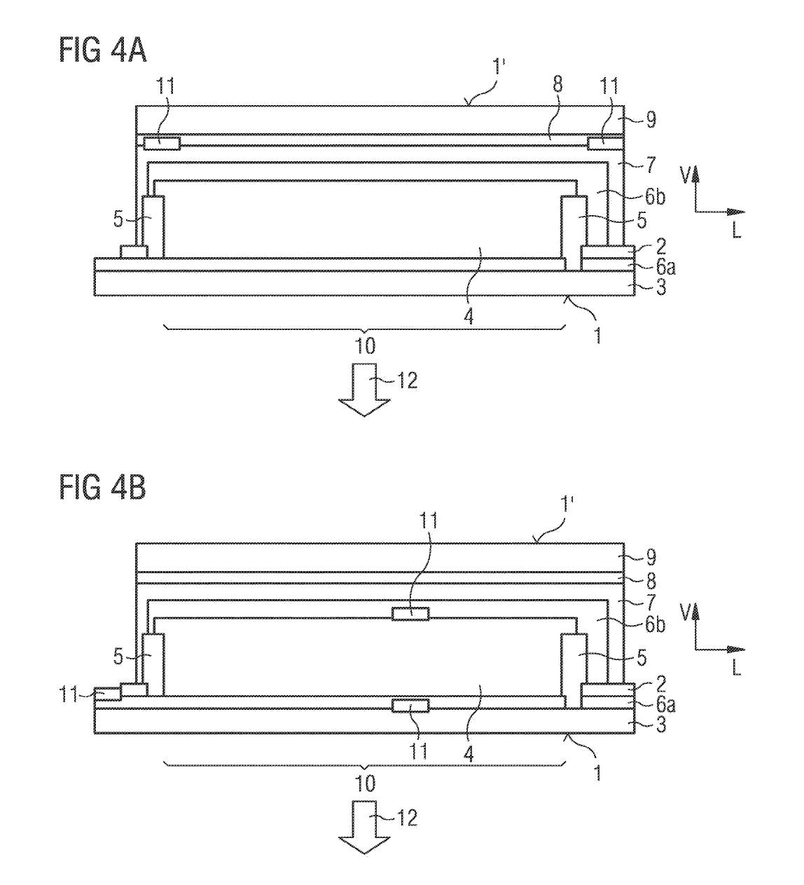

Embodiments are shown in conjunction with FIGS. 4A and 4B, in which the marking elements 11 are arranged at different points in the lateral direction L. In the embodiment of FIG. 4B, the marking elements 11 are arranged outside the illuminated area in the edge region of the main surface 1. The marking elements 11 can be read out in this case from the front side of the optoelectronic component 100, which includes the illuminated area 10, or from its rear surface.

In the embodiment of FIG. 4B, the marking elements 11 are arranged inside the illuminated area 10 and outside the illuminated area 10 and can each be read out from the front side at the main surface 1, which includes the illuminated area 10.

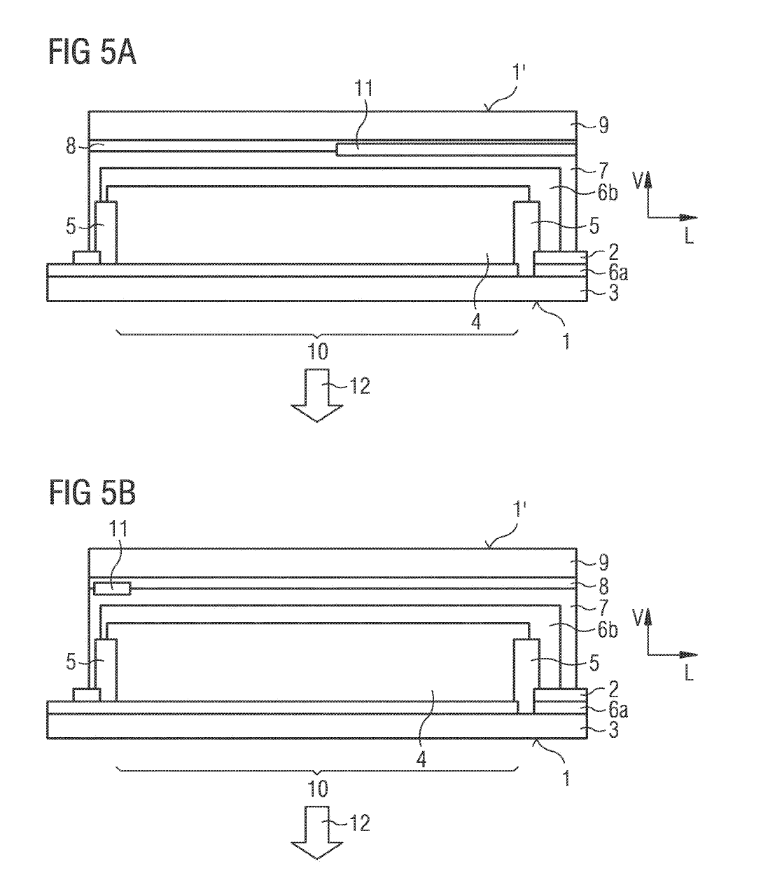

In conjunction with FIGS. 5A and 5B, it is explained that the marking elements 11 can be embodied in different sizes. It is thus possible that a marking element 11 occupies an area of at least 10%, in particular at least 25% of the entire main surface of the optoelectronic component. Furthermore, it is possible that a marking element occupies at most 5% of this area, see FIG. 5B in this regard.

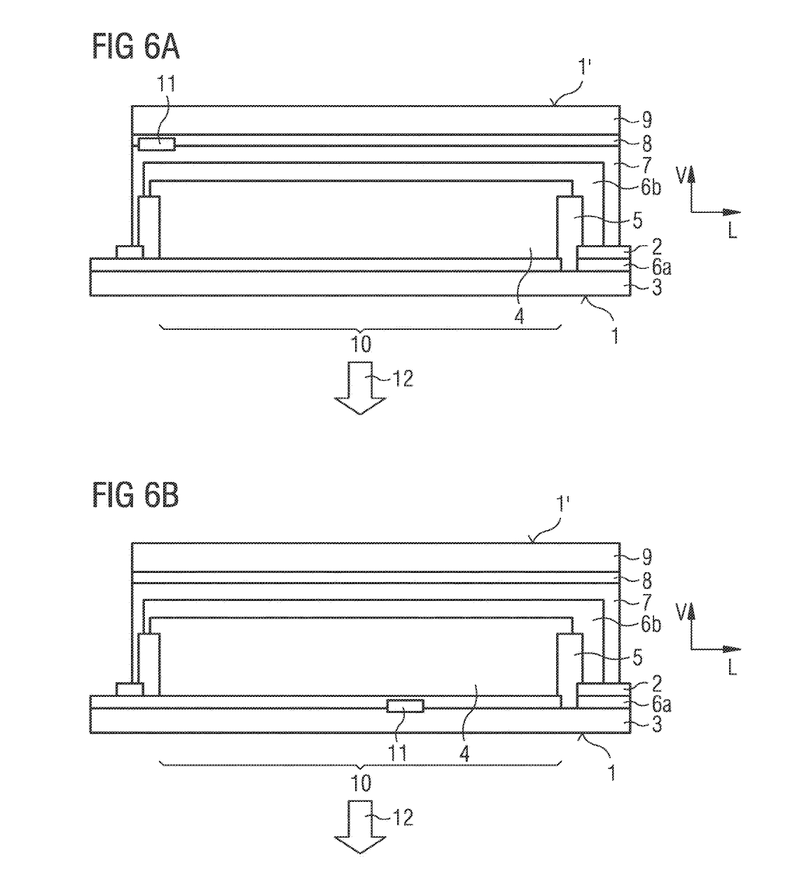

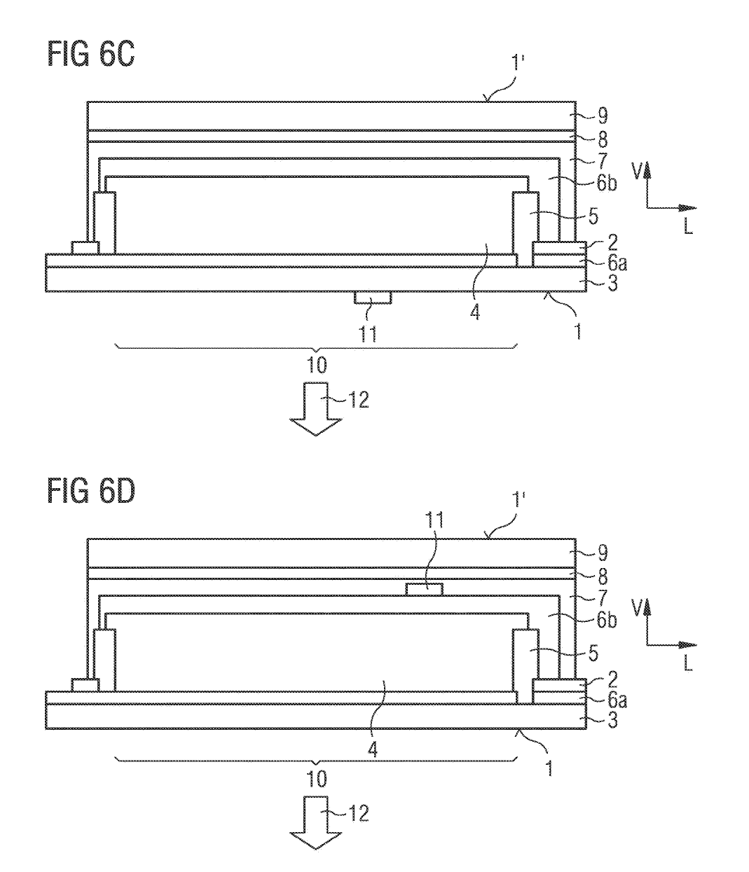

It is described in conjunction with FIGS. 6A, 6B, 6C, and 6D that the marking elements described here can be arranged at different points of the optoelectronic component 100 in the vertical direction V.

FIG. 6A shows an embodiment in which the marking element is arranged on the encapsulation 7 between the encapsulation 7 and the bonding agent 8. Such a marking element 11 is not located inside the encapsulation of the optoelectronic component 100 and is therefore preferably formed using materials which are less sensitive to moisture and atmospheric gases than the organic layer stack 4.

In the embodiment of FIG. 6B, the marking element 11 is located between the carrier 3 and the first electrode 6A, and therefore inside the encapsulation of the optoelectronic component 100, which enables the use of sensitive phosphors.

In the embodiment of FIG. 6C, the marking element 11 is arranged at the side of the carrier 3 facing away from the layer stack 4 and therefore outside the encapsulation. Such a marking element 11 is also particularly easily applicable subsequently, which is accompanied by the disadvantage that it is poorly protected from chemical and mechanical stresses.

In the embodiment of FIG. 6D, the marking element 11 is arranged on the second electrode 6b inside the encapsulation 7. Such a marking element 11 also profits from the encapsulation for the organic layer stack 4.

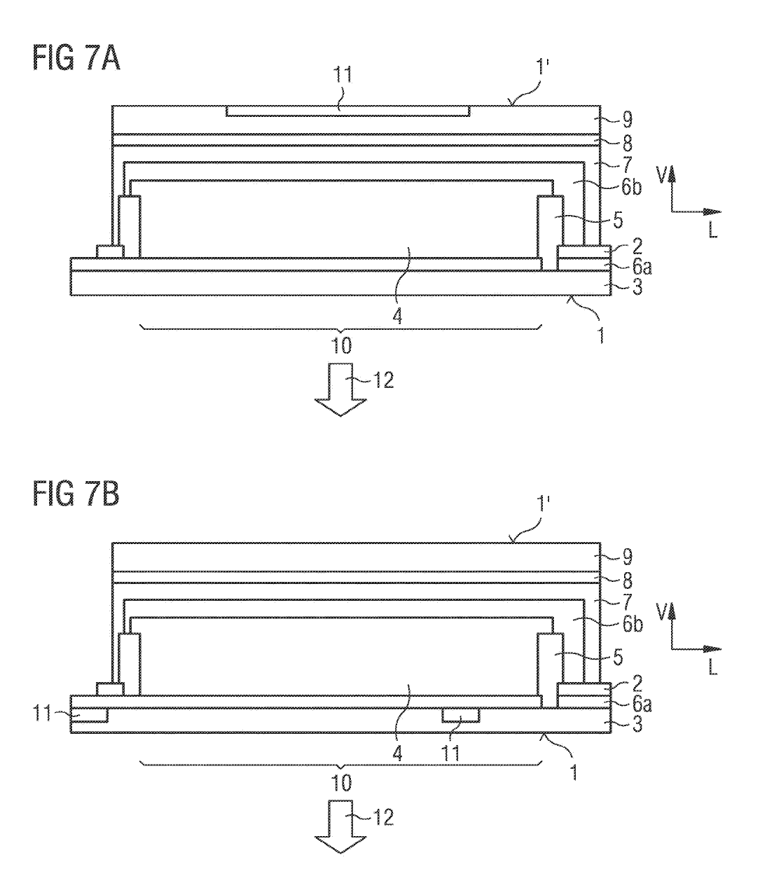

In the embodiments of FIGS. 7A and 7B, the marking elements are arranged inside the cover 9 and/or inside the carrier 3. Such marking elements can already be manufactured during the manufacturing of the cover 9 and/or the carrier 3, whereby the process sequence for the production of the optoelectronic component does not have to be modified in comparison to optoelectronic components without marking element 11 and nonetheless there is good chemical and mechanical protection of the marking elements.

Overall, an optoelectronic component 100 described here can be identified particularly simply and therefore differentiated from components of another construction. The marking of the optoelectronic component facilitates the exchange thereof and prevents counterfeits of the components. The optoelectronic components may be identified rapidly, which facilitates the troubleshooting and the complaint by the customer. By way of the identification options, for example, upon the use of the optoelectronic component in a motor vehicle headlight, clearing up traffic offenses can be facilitated, by coding items of vehicle type information in the marking elements. The marking elements described here can be produced particularly simply and cost-effectively by printing processes, for example.

Furthermore, it is possible to introduce the marking elements described here into other parts (not shown) of the optoelectronic component. For example, the optoelectronic component may include a decoupling film at its radiation exit side, at least in the region of the illuminated area 10, which increases the probability of the light exit from the optoelectronic component. A marking element described here can also be applied below or in or on such a decoupling film. The described marking elements advantageously do not influence the appearance of the optoelectronic component in the turned-on state or in the turned-off state.

The invention is not restricted thereto by the description on the basis of the embodiments. Rather, the invention includes every novel feature and every combination of features, which in particular includes every combination of features in the patent claims, even if this feature or this combination is not itself explicitly specified in the patent claims or embodiments.

### LIST OF REFERENCE NUMERALS

1, 1′ main surface
2 contact points
3 carrier
4 layer stack
5 insulation
6a first electrode
6b second electrode
7 encapsulation
8 bonding agent
9 cover
10, 10′ illuminated area
11 marking element
12, 12′ light
100 optoelectronic component

1. An optoelectronic component comprising
an organic layer stack, in which light is generated in operation of the optoelectronic component,
at least one marking element, by means of which the optoelectronic component is identifiable, wherein
the at least one marking element can be read out under irradiation using electromagnetic radiation from the nonvisible spectral range,
the at least one marking element can be read out at a main surface of the optoelectronic component, and
wherein the at least one marking element is arranged at or under the main surface in the region of the illuminated area.

2. The optoelectronic component as claimed in claim 1,
wherein the main surface comprises an illuminated area, through which at least a part of the light generated in operation leaves the optoelectronic component.

3. The optoelectronic component as claimed in claim 1,
wherein the at least one marking element is not visible to the human observer and can exclusively be read out under irradiation using the electromagnetic radiation from the nonvisible spectral range.

4. The optoelectronic component as claimed in claim 1,
wherein the at least one marking element, upon the irradiation using the electromagnetic radiation from the nonvisible spectral range, emits further electromagnetic radiation from the nonvisible spectral range, which is different from the electromagnetic radiation from the nonvisible spectral range.

5. The optoelectronic component as claimed in the claim 1,
wherein the at least one marking element is arranged in a lateral direction at or under the main surface laterally to the illuminated area.

6. (canceled)

7. The optoelectronic component as claimed in claim 1,
wherein the at least one marking element is arranged between two parts of the optoelectronic component.

8. The optoelectronic component as claimed in claim 1,
wherein the at least one marking element is arranged inside a part of the optoelectronic component.

9. The optoelectronic component as claimed in claim 8,
wherein the part is selected from the following group: main surface, carrier, organic layer stack, insulation, first electrode, second electrode, encapsulation, bonding agent, cover.

10. The optoelectronic component as claimed in claim 1,
comprising at least two marking elements, wherein the marking elements are arranged offset and/or spaced apart in relation to one another in a lateral direction and/or a vertical direction.

11. The optoelectronic component as claimed in claim 1,
wherein the at least one marking element is formed using a sensitive phosphor and the at least one marking element is arranged inside an encapsulation of the optoelectronic component.

12. A method for exchanging an optoelectronic component comprising the following steps:
irradiating a main surface of an optoelectronic component using electromagnetic radiation from the nonvisible spectral range,
reading out at least one marking element, which can be read out under the irradiation using the electromagnetic radiation from the nonvisible spectral range and which is arranged at or under the main surface,
identifying the optoelectronic component on the basis of the marking element, and
exchanging the optoelectronic component with a structurally-equivalent optoelectronic component,
wherein the optoelectronic component comprises,
an organic layer stack, in which light is generated in operation of the optoelectronic component, and
at least one marking element, by means of which the optoelectronic component is identifiable, wherein the at least one marking element can be read out under irradiation using electromagnetic radiation from the nonvisible spectral range, the at least one marking element can be read out at a main surface of the optoelectronic component, and
wherein the at least one marking element is arranged at or under the main surface in the region of the illuminated area.

13. (canceled)
